(19) United States
(12) Patent Application Publication
(10) Pub. No.: US 2026/0245838 A1
(43) Pub. Date: Aug. 20, 2026

(54) SUBSTRATE TREATING APPARATUS

(71) Applicants: Samsung Electronics Co., Ltd., Suwon-si (KR); UIF (University Industry Foundation), Yonsei University, Seoul (KR)

(72) Inventors: Junghwan Um, Suwon-si (KR); Keonwook Kang, Suwon-si (KR); Sunil Moon, Suwon-si (KR); Younseon Wang, Suwon-si (KR); Sungil Cho, Suwon-si (KR); Bonseung Goo, Suwon-si (KR); Hansin Bae, Suwon-si (KR)

(73) Assignees: Samsung Electronics Co., Ltd., Suwon-si (KR); UIF (University Industry Foundation), Yonsei University, Seoul (KR)

(21) Appl. No.: 19/329,949

(22) Filed: Sep. 16, 2025

(30) Foreign Application Priority Data
Feb. 19, 2025 (KR) 10-2025-0021657
Mar. 10, 2025 (KR) 10-2025-0030702

(51) Int. Cl. H01J 37/32

(52) U.S. Cl. CPC H01J 37/32724; H01J 37/32642; H01J 37/32816; H01J 2237/002

(57) ABSTRACT

A substrate processing apparatus according to embodiments comprises: a chamber; a plasma excitation member that allows energy to be applied for excitation of plasma; and a supporting member positioned inside the chamber to support a substrate, wherein the supporting member is provided with material in which at least a portion of an outer surface comprises boron carbide.

### CROSS-REFERENCE TO RELATED APPLICATIONS

This present application claims priority to and the benefit under 35 U.S.C. § 119 (a)-(d) of Korean Patent Application No. 10-2025-0021657, filed on Feb. 19, 2025, in the Korean Intellectual Property Office and of Korean Patent Application No. 10-2025-0030702, filed on Mar. 10, 2025, in the Korean Intellectual Property Office, the entire disclosures of which are incorporated herein by reference.

### FIELD

The present disclosure relates to a substrate processing apparatus.

### BACKGROUND

To manufacture a semiconductor device, various processes such as photolithography, etching, ashing, ion implantation, thin film deposition, and cleaning are performed on the substrate to form a desired pattern. Among them, the etching process is a process of removing a selected heating region among the films formed on the substrate, and wet etching and dry etching are used.

Among them, an etching device using plasma is used for dry etching. In general, in order to form plasma, an electromagnetic field is formed in the inner space of the chamber, and the electromagnetic field excites the process gas provided in the chamber into a plasma state.

Plasma refers to an ionized gas state composed of ions, electrons, radicals, etc. Plasma is generated by very high temperatures, strong electric fields, or RF electromagnetic fields. The semiconductor device manufacturing process uses plasma to perform an etching process. The etching process is performed by colliding ion particles contained in the plasma with the substrate.

### SUMMARY

Embodiments are to provide a substrate processing apparatus capable of improving the lifespan of a component.

However, the problems to be solved by the embodiments of the present disclosure are not limited to the above-described problems and may be extended in various ways within the scope of the technical idea included in the present disclosure.

A substrate processing apparatus according to aspects may include a chamber; a plasma excitation member that allows energy to be applied for excitation of plasma; and a supporting member positioned inside the chamber to support a substrate, wherein the supporting member is provided with material in which at least a portion of an outer surface of the supporting member comprises boron carbide represented by the chemical formula,

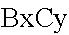

wherein x, y are positive real numbers.

A substrate processing apparatus according to aspects may include a chamber; a plasma excitation member for applying energy for plasma excitation; and a supporting member positioned inside the chamber to support a substrate, wherein the supporting member includes: a dielectric plate; and a focus ring positioned around an outer periphery of the dielectric plate, and wherein at least a portion of an outer surface of the focus ring is provided with a material including boron carbide represented by the following chemical formula,

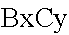

wherein x, y are positive real numbers.

According to aspects, a substrate processing apparatus may include: a chamber; a plasma excitation member that allows energy to be applied for excitation of plasma; a supporting member positioned inside the chamber to support a substrate; a chiller connected to the supporting member; and a gas supply member connected to the chamber, wherein the supporting member includes: a dielectric plate; a focus ring positioned on an outer periphery of the dielectric plate; and an insulation ring positioned around an outer periphery of the focus ring, wherein at least a portion of an outer surface of the focus ring and the insulation ring is provided with a material including boron carbide represented by the following chemical formula,

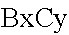

wherein x, y are positive real numbers.

According to embodiments, a substrate processing apparatus capable of improving the lifespan of components may be provided.

According to embodiments, provided is a method for processing a substrate comprising: with a plasma excitation member applying energy to excite plasma; and supporting the substrate with a supporting member positioned inside a chamber, wherein the supporting member is provided with material in which at least a portion of an outer surface of the supporting member comprises boron carbide represented by the chemical formula,

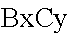

wherein x, y are positive real numbers

### BRIEF DESCRIPTION OF THE DRAWINGS

FIG. 1 is a drawing showing a substrate processing apparatus according to embodiments.

FIG. 2 is a perspective view of the baffle of FIG. 1.

FIG. 3 is a partial cut-away perspective view of the baffle of FIG. 1.

FIG. 4 is a cross-sectional view of the focus ring of FIG. 1.

FIG. 5 and FIG. 6 are graphs showing the degree of occurrence of silicon fluorine bonds according to carbon doping.

FIG. 7 is a graph showing a sticking coefficient in silicon and B₄C (001) plane.

FIG. 8 is a diagram showing the relationship between the size and strength of the crystal grains of boron carbide.

FIG. 9 is a cross-sectional view of a focus ring according to embodiments.

FIG. 10 is a cross-sectional view of the insulation ring of FIG. 1.

FIG. 11 is a cross-sectional view of an insulation ring according to embodiments.

FIG. 12 is a cross-sectional view of the pressure control member of FIG. 1.

FIG. 13 is a cross-sectional view of a pressure control member according to embodiments.

FIG. 14 is a cross-sectional view of the baffle of FIG. 1.

FIG. 15 is a cross-sectional view of a baffle according to embodiments.

FIG. 16 is a diagram illustrating a substrate processing apparatus according to embodiments.

FIG. 17 is a cross-sectional view of the baffle of FIG. 16.

FIG. 18 is a cross-sectional view of a baffle according to embodiments.

FIG. 19 is a diagram illustrating a substrate processing apparatus according to embodiments.

### DETAILED DESCRIPTION

Hereinafter, various embodiments of the present disclosure will be described in detail with reference to the accompanying drawings so that those skilled in the art may easily implement the present disclosure. The present disclosure may be implemented in several different forms and is not limited to the embodiments described herein.

In order to clearly explain the present disclosure, parts that do not have a relationship with the explanation are omitted, and identical or similar component is assigned the same reference numerals throughout the specification.

In addition, the size and thickness of each component shown in the drawing are arbitrarily shown for better understanding and ease of description, so the present disclosure is not necessarily limited to what is shown. In the drawings, the thickness of layers, films, panels, regions, etc., are exaggerated for clarity. And, in the drawings, for the convenience of explanation, the thickness of some layers and regions is exaggerated.

Additionally, when a part of a layer, film, region, substrate, etc. is referred to be “above” or “on” another part, this may include not only cases where it is “directly on” another part, but also cases where there are intervening elements in between. In contrast, when an element is referred to as being “directly on” another element, there are no intervening elements present. In addition, being “above” or “on” a reference part means being positioned above or below the reference part, and does not necessarily mean being positioned “above” or “on” it in the opposite direction of gravity.

In addition, throughout the specification, when a part is referred to “include” a certain component, this means that it may further include other components rather than excluding other components, unless specifically stated to the contrary.

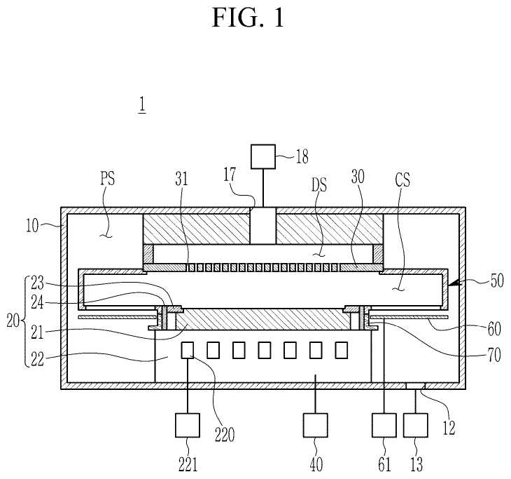

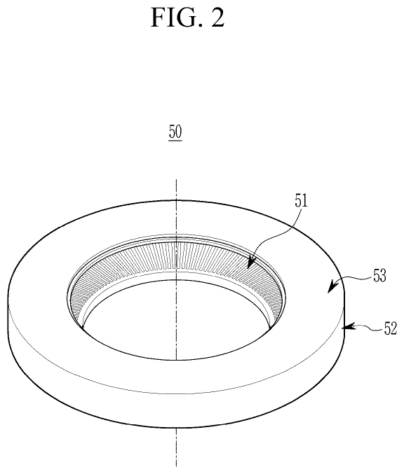

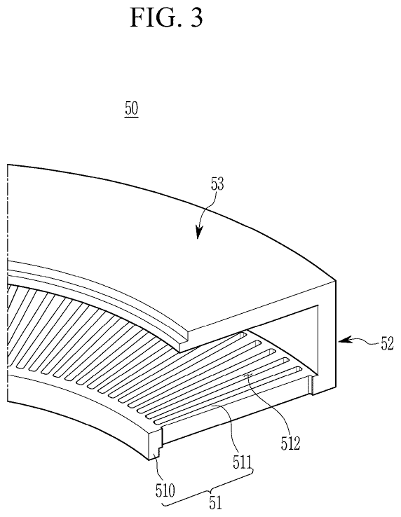

FIG. 1 is a view illustrating a substrate processing apparatus 1 according to embodiments. FIG. 2 is a perspective view of a baffle 50 of FIG. 1. FIG. 3 is a partially cut-away perspective view of the baffle 50 of FIG. 1.

Referring to FIGS. 1 to 3, a substrate processing apparatus 1 according to embodiments may include a chamber 10, a supporting member 20, a plasma excitation member 30, a source power supply unit 40, a baffle 50, and a pressure control member 60.

The substrate processing apparatus 1 processes a substrate using plasma. For example, the substrate processing apparatus 1 may perform an etching process or the like using the excited plasma. The substrate may be a wafer or the like for manufacturing semiconductor devices.

The chamber 10 provides a process space PS in which a substrate processing process is performed. The chamber 10 may have an internal process space PS and may be provided in a sealed shape. The chamber 10 may be made of a metal material. For example, the chamber 10 may be made of an aluminum material. The chamber 10 may be grounded.

An exhaust hole 12 may be positioned at one side of the chamber 10. For example, the exhaust hole 12 may be positioned in a lower area of the chamber 10. Reaction by-products generated during the substrate treatment process and gases remaining in the inner space of the chamber 10 may be discharged to the outside through the exhaust hole 12. The inside of the chamber 10 may be depressurized to a predetermined pressure by the exhaust process. An exhaust member 13 may be connected to the exhaust hole 12 of the chamber 10. The exhaust member 13 allows negative pressure for exhausting to be applied to the inside of the chamber 10. The exhaust member 13 may include at least one pump. In addition, the exhaust member 13 is provided to include a valve, etc., so that the flow rate of gas discharged through the exhaust hole 12 may be adjusted according to the degree of opening and closing of the valve.

A gas inlet 17 may be positioned at one side of the chamber 10. The gas inlet 17 may be positioned above the chamber 10. For example, the gas inlet 17 may be positioned in a central region of the upper wall of the chamber 10. The gas inlet 17 is provided as a hole, a nozzle, or the like, and provides a path through which the process gas flows into the chamber 10.

A gas supply member 18 may be connected to one side of the chamber 10. The gas supply member 18 may be connected to the gas inlet 17. The gas supply member 18 may supply a process gas into the chamber 10. For example, the process gas may be H₂, HF, Cl₂, CH₂F₂, NH₃, carbon fluoride (CxFy), or the like. In addition, the process gas may be a combination of at least two gases selected from the group consisting of H₂, HF, Cl₂, CH₂F₂, NH₃, and carbon fluoride (CxFy). When the process gas is a combination of a plurality of gases, the gas supply member 18 may store each gas individually and supply each gas individually to the chamber 10. In addition, when the process gas is a combination of multiple gases, the gas supply member 18 individually stores and supplies each gas, and each gas may be mixed with each other during the process of being introduced into the interior of the chamber 10. The gas supply member 18 may supply a process gas for excitation of the HF plasma. For example, the process gas supplied by the gas supply member 18 may include NH₃ and carbon fluoride (CxFy). In addition, the process gas supplied by the gas supply member 18 may include H₂ and carbon fluoride (CxFy). In addition, the process gas supplied by the gas supply member 18 may include HF and carbon fluoride (CxFy).

The supporting member 20 is positioned inside the chamber 10. The supporting member 20 may be positioned under the process space PS. The supporting member 20 supports the substrate. The supporting member 20 may adsorb the substrate using an electrostatic force. The supporting member 20 may be made of a material in which at least a portion of an outer surface includes boron carbide. The details of this will be described later.

The supporting member 20 may include a dielectric plate 21, a body 22, a focus ring 23, and an insulation ring 24.

The dielectric plate 21 is positioned upper part the supporting member 20. The dielectric plate 21 may be provided in a plate structure having a predetermined thickness. The outer circumference of the dielectric plate 21 may be circular. The outer surface of the dielectric plate 21 may be provided as a dielectric substance. A substrate is placed on the upper surface of the dielectric plate 21. The area of the upper surface of the dielectric plate 21 may be provided smaller than the area of the substrate. The upper surface of the dielectric plate 21 may have a radius smaller than that of the substrate. Accordingly, when the substrate is positioned on the upper surface of the dielectric plate 21, the edge region of the substrate may be positioned outside the dielectric plate 21.

An internal electrode may be positioned inside the dielectric plate 21. The internal electrode may be provided in a shape corresponding to the upper surface of the dielectric plate 21. The internal electrode may be electrically connected to an adsorption power source. The adsorption power source may include a DC power source. An electrostatic force is generated between the internal electrode and the substrate by the voltage applied by the adsorption power source, and the electrostatic force causes the substrate to be adsorbed to the dielectric plate 21.

A heat transfer medium supply flow path may be formed inside the dielectric plate 21. The heat transfer medium supply flow path is connected to the upper surface of the dielectric plate 21 to provide a path through which the heat transfer gas is supplied to the upper surface of the dielectric plate 21. The heat transfer gas may be an inert gas. For example, the heat transfer gas may be helium (He). When the heat transfer gas is supplied to the upper surface of the dielectric plate 21 while the substrate is adsorbed on the upper surface of the dielectric plate 21, the space formed between the lower surface of the substrate and the dielectric plate 21 is filled with the heat transfer gas. The heat transfer gas serves as a medium for transferring heat from the substrate to the supporting member 20.

The body 22 is positioned at the lower part of the supporting member 20. The dielectric plate 21 may be positioned on the upper portion of the body 22. For example, the dielectric plate 21 may be attached to the body 22 by an adhesive layer. The dielectric plate 21 may be positioned above the upper central region of the body 22.

A refrigerant flow path 220 may be formed inside the body 22. The refrigerant flow path 220 provides a path through which the refrigerant flows inside the body 22. For example, the refrigerant flow path 220 may be formed in a spiral shape. Additionally, the refrigerant flow path 220 may be arranged in ring-shaped paths having different radii and having the same center. At this time, the refrigerant flow path 220 may be configured so that ring-shaped paths are connected to each other.

The refrigerant flow path 220 may be connected to the chiller 221. The chiller 221 may supply a refrigerant to the refrigerant flow path 220 and recover the refrigerant from the refrigerant flow path 220. Accordingly, the refrigerant may circulate between the refrigerant flow path 220 and the chiller 221.

The refrigerant circulates through the refrigerant flow path 220 and cools the body 22. As the body 22 cools down, it cools the dielectric plate 21 and the substrate. That is, heat of the substrate may be transferred to the cooled body 22 through the dielectric plate 21. For example, in order to implement a low-temperature etching process during the substrate processing process, the chiller 221 may allow the dielectric plate 21 to be cooled to below 0° C. through refrigerant circulation.

At least a portion of the body 22 may be made of a metal material. For example, the entire body 22 may be made of a metal material. The body 22 may be formed of an aluminum material. Accordingly, the body 22 may function as an electrode.

The focus ring 23 may be disposed in an upper outer region of the supporting member 20. The focus ring 23 may be disposed around an outer periphery of the upper portion of the dielectric plate 21. The focus ring 23 may be disposed on the dielectric plate 21. Also, the focus ring 23 may be positioned on the upper edge region of the body 22. The focus ring 23 may be provided in a ring shape. The upper part of the focus ring 23 may be formed with a step so that the outer part is higher than the inner part. The upper inner portion of the focus ring 23 may be positioned at a height corresponding to the upper surface of the dielectric plate 21. When the substrate is positioned on the supporting member 20, the upper inner portion of the focus ring 23 may be positioned below the edge region of the substrate. When the substrate is positioned on the supporting member 20, the upper outer portion of the focus ring 23 may be positioned to surround the edge area of the substrate. The focus ring 23 improves the uniformity of the density distribution of the plasma. The focus ring 23 may be worn out during use. When the degree of wear of the focus ring 23 increases, the performance of adjusting the density distribution of the plasma decreases. Accordingly, the focus ring 23 is replaced after being used for a certain period of time or a certain number of times.

The insulation ring 24 may be disposed in the upper outer region of the supporting member 20. The insulation ring 24 may be disposed around the outer periphery of the focus ring 23. The insulation ring 24 may be disposed on the body 22. Alternatively, the insulation ring 24 may extend downward from the outer circumference of the focus ring 23 to surround the outer circumference of the body 22.

The plasma excitation member 30 allows energy for excitation of plasma to be applied to the process space PS. The lower surface of the plasma excitation member 30 may be positioned inside the chamber 10. For example, the plasma excitation member 30 may be manufactured separately from the chamber 10 and connected to the chamber 10. Alternatively, the plasma excitation member 30 may be integrally provided with the upper structure of the chamber 10. That is, the upper structure of the chamber 10 may function as the plasma excitation member 30.

The plasma excitation member 30 may be positioned above the process space PS. The plasma excitation member 30 may be provided to have a predetermined area as a conductive material. The plasma excitation member 30 may be positioned opposite the support member 20 in an upward and downward direction.

A distribution space DS may be formed in a region spaced upward from a lower surface of the plasma excitation member 30. The distribution space DS may be positioned above the plasma excitation member 30. That is, the plasma excitation member 30 may be disposed inside the chamber 10. In addition, the upper surface of the plasma excitation member 30 and the upper wall of the chamber 10 are spaced apart, so that a distribution space DS may be formed between the upper surface of the plasma excitation member 30 and the upper wall of the chamber 10. In addition, the distribution space DS may be formed inside the plasma excitation member 30. The distribution space DS is connected to the gas inlet 17. A distribution hole 31 connecting the distribution space DS and a lower surface of the plasma excitation member 30 may be formed in the plasma excitation member 30. Accordingly, the process gas supplied through the gas inlet unit 17 may be supplied to the lower side of the plasma excitation member 30 through the distribution space DS and the distribution hole 31.

The source power supply unit 40 provides power for plasma excitation. The source power supply unit 40 may be electrically connected to the supporting member 20. The source power supply unit 40 may be electrically connected to a region provided as a conductive material in the body 22 of the supporting member 20. The source power supply unit 40 may include a high frequency power source that generates high frequency power. The source power supply unit 40 may include RF power.

The process gas introduced into the chamber 10 may be excited into plasma by an electric field formed inside the chamber 10. Specifically, the process gas may be excited into plasma by a capacitively coupled plasma (CCP) source. The capacitively coupled plasma source may include an upper electrode and a lower electrode. The upper electrode and the lower electrode may be disposed in an upward and downward direction, facing each other inside the chamber 10. By applying high frequency power to at least one of the upper electrode and the lower electrode, an electromagnetic field is formed in a space between the upper electrode and the lower electrode, and the process gas supplied to the space may be excited in a plasma state. The upper electrode may be the plasma excitation member 30, and the lower electrode may be a metal material region of the body 22. High frequency power may be applied to one of the upper electrode and the lower electrode, and the other may be grounded. For example, the upper electrode may be grounded, and high frequency power may be applied to the lower electrode. In addition, the lower electrode may be grounded, and high frequency power may be applied to the upper electrode. In addition, high frequency power may be applied to both the upper electrode and the lower electrode. FIG. 1 illustrates a case where high frequency power is applied to the lower electrode.

The baffle 50 divides a space positioned above the supporting member 20 and a space positioned below the chamber 10 from each other. The baffle 50 may adjust the flow rate of the fluid exhausted to the outside of the chamber 10 in a space positioned above the supporting member 20. That is, reaction by-products generated during the substrate processing process may flow to the exhaust hole 12 via the baffle 50. A baffle 50 is disposed around the outer periphery of the supporting member 20. The baffle 50 may be disposed around the outer periphery of the focus ring 23. The baffle 50 may be disposed around the outer periphery of the insulation ring 24. An insulation ring 24 is disposed between the baffle 50 and the focus ring 23, so that the baffle 50 and the focus ring 23 may be electrically insulated from each other. The baffle 50 may have a ring structure. The center of the baffle 50 may be positioned to correspond to the center of the supporting member 20.

The baffle 50 may include an exhaust control part 51 and partition portions 52 and 53.

The exhaust control part 51 provides a lower structure of the baffle 50. The exhaust control part 51 may have a ring structure. The exhaust control part 51 may be disposed around the outer periphery of the supporting member 20. The exhaust control part 51 may be disposed around the outer periphery of the focus ring 23. The exhaust control part 51 may be disposed around the outer periphery of the insulation ring 24.

The exhaust control part 51 may be disposed on a horizontal plane. The center of the exhaust control part 51 may be disposed to correspond to the center of the supporting member 20. The center of the exhaust control part 51 may be disposed to correspond to the center of the dielectric plate 21. The center of the exhaust control part 51 may be positioned to correspond to the center of the focus ring 23. The exhaust control part 51 may have a predetermined width in a radial direction.

The exhaust control part 51 may include a connection portion 510 and an exhaust portion 511.

The connection portion 510 may be positioned at an inner end portion of the exhaust control part 51 facing the supporting member 20. The exhaust portion 511 may extend radially outward from the connection portion 510 and may be positioned around the outer periphery of the connection portion 510. The thickness of the connection portion 510 may be greater than the thickness of the exhaust portion 511. The width of the exhaust portion 511 in the radial direction is provided to be larger than the width of the connection portion 510.

The exhaust portion 511 may occupy most areas of the exhaust control part 51.

A plurality of discharge holes 512 may be positioned in the exhaust control part 51. The discharge holes 512 are formed to penetrate between an upper surface and a lower surface of the exhaust control part 51. The discharge hole 512 may be formed in the exhaust portion 511. The discharge hole 512 may have a long slit shape in one direction. While plasma is prevented or minimized from escaping through the discharge hole 512, the size of the discharge hole 512 may be adjusted so that reaction by-products generated in the substrate processing process are effectively discharged through the discharge hole 512.

The partition portions 52 and 53 provide an upper structure of the baffle 50. The partition portions 52 and 53 are provided to surround the space positioned above the exhaust control part 51. Accordingly, the partition portions 52 and 53 may allow the plasma excitation space CS to be partitioned from other spaces.

Upper portions of the partition portions 52 and 53 may be connected to the plasma excitation member 30.

The partition portions 52 and 53 may be positioned above the exhaust control part 51. The partition portions 52 and 53 may be integrally formed with the exhaust control part 51. Alternatively, the partition portions 52 and 53 may be manufactured separately from the exhaust control part 51 and connected to the exhaust control part 51. The partition portions 52 and 53 may be provided in a ring structure. The partition portions 52 and 53 are positioned to surround the space positioned above the supporting member 20, and a plasma excitation space CS is formed inside the partition portions 52 and 53. The partition portions 52 and 53 may surround a space between the plasma excitation member 30 and the supporting member 20.

The partition portions 52 and 53 may include a side partition portion 52 and an upper partition portion 53.

The side partition portion 52 may be connected to an outer end of the exhaust control part 51. The side partition portion 52 may have a ring structure. The side partition portion 52 may extend upward from the outer end of the exhaust control part 51. The side partition portion 52 may have a predetermined length in an upward and downward direction.

The upper partition portion 53 may be connected to the upper portion of the side partition portion 52. The upper partition portion 53 may have a ring structure. The upper partition portion 53 may extend from the upper portion of the side partition portion 52 toward the center of the baffle 50. An inner end of the upper partition portion 53 may be connected to the plasma excitation member 30. The inner end of the upper partition portion 53 has a structure in direct contact with the plasma excitation member 30 and may be connected to the plasma excitation member 30.

The process gas introduced into the chamber 10 is excited into plasma. In this case, a plasma excitation space CS surrounded by a baffle 50 is formed above the supporting member 20. The process gas introduced into the chamber 10 may be excited into the plasma while being positioned in the plasma excitation space CS. The process space PS inside the chamber 10 is divided into a plasma excitation space CS and other spaces by a baffle 50. Accordingly, a higher-density plasma may be excited in a region positioned above the supporting member 20.

The baffle 50 may be grounded. For example, the baffle 50 may be connected to the ground member 70. The ground member 70 may be connected to a lower end portion of the baffle 50. For example, the ground member 70 may have a ring structure and may be disposed around the outer periphery of the supporting member 20. The ground member 70 may be disposed around the outer periphery of the insulation ring 24 and connected to the lower end of the baffle 50. The ground member 70 may be connected to the exhaust control part 51. The ground member 70 may be connected to the connection part 510. The ground member 70 may be grounded. In addition, the baffle 50 may be grounded through the ground member 70. The plasma excitation member 30 may be grounded through a baffle 50 and a ground member 70.

A pressure control member 60 may be disposed below the baffle 50. The pressure control member 60 may be disposed around the outer periphery of the supporting member 20. The pressure control member 60 may be disposed around the outer periphery of the ground member 70. The pressure control member 60 may have a ring structure having a predetermined width in a radial direction. The width of the pressure control member 60 in the radial direction may correspond to the width of the exhaust control part 51 in the radial direction. The width of the pressure control member 60 in the radial direction may correspond to the width of the exhaust part 511 in the radial direction. The pressure control member 60 may be positioned opposite the discharge hole 512 in an upward and downward direction.

The pressure control member 60 may be provided to be movable in an upward and downward direction. For example, the pressure control member 60 may be connected to the elevating member 61. The elevating member 61 may provide power for the pressure control member 60 to move in an upward and downward direction. Depending on the up or down position of the pressure control member 60, the amount of exhaust pressure applied to the exhaust hole 512 may be adjusted.

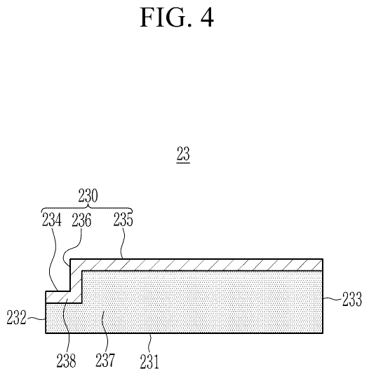

FIG. 4 is a cross-sectional view of the focus ring 23 of FIG. 1.

Referring to FIG. 4, as the focus ring 23 has a ring structure, the outer surface of the focus ring 23 may include an upper surface 230, a lower surface 231, an inner side surface 232 positioned between the upper surface 230 and the lower surface 231 and facing a hole formed on the inner side and a dielectric plate 21, and an outer side surface 233 positioned between the upper surface 230 and the lower surface 231 and facing the chamber 10 in the opposite direction of the inner side surface 232. In addition, the upper surface 230 of the focus ring 23 may include a first surface 234 positioned inside, a second surface 235 positioned outside, and a connection surface 236 positioned between the first surface 234 and the second surface 235. As described above, the first surface 234 may be positioned below the second surface 235.

At least a portion of the outer surface of the focus ring 23 may be made of a material including boron carbide. The focus ring 23 may include a core 237 and a protection layer 238. The core 237 and the protection layer 238 may be formed of different materials. The protection layer 238 may include boron carbide represented by Chemical Formula 1. x, y are positive real numbers.

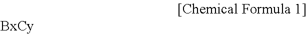

For example, boron carbide included in the protection layer 238 may be B₂C, B₄C, B₅C, B₆C, B₁₃C₂, B₁₃C₃, or B₅₀C₂. Furthermore, the boron carbide included in the protection layer 238 may be a combination of at least two materials selected from the group consisting of B₂C, B₄C, B₅C, B₆C, B₁₃C₂, B₁₃C₃, B₅₀C₂, etc.

In addition, boron carbide included in the protection layer 238 may be represented by boron carbide as shown in Chemical Formula 2. y1 is a positive real number greater than 1.

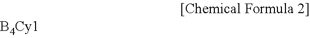

That is, boron carbide included in the protection layer 238 may have a higher ratio of carbon to boron than B₄C.

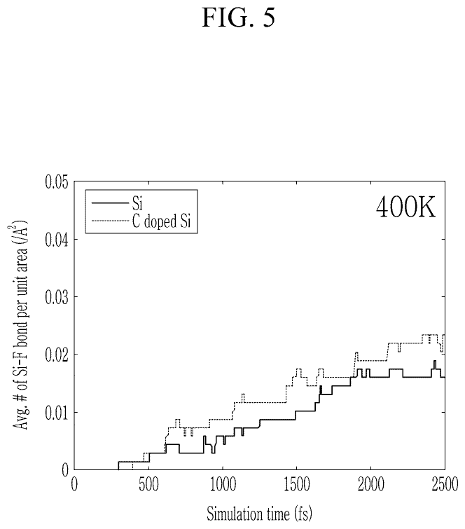

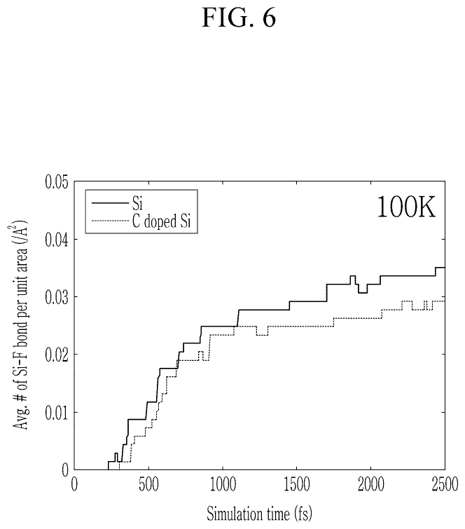

FIGS. 5 and 6 are graphs showing the degree of occurrence of silicon fluorine bonds according to carbon doping.

FIG. 5 is a graph showing the degree to which silicon fluorine bonds occur in silicon and carbon doped silicon over time when the temperature is 400K. FIG. 6 is a graph showing the degree to which silicon fluorine bonds occur in silicon and carbon doped silicon over time when the temperature is 100K.

The graph is created by simulating when silicon and carbon-doped silicon are exposed to HF plasma, respectively, using Molecular dynamics. Forcefield (interatomic potential) is implemented using ReaxFF.

Referring to FIG. 5, the degree of occurrence of silicon fluorine bonds over time when the temperature is 400K is greater in carbon-doped silicon than in silicon.

Referring to FIG. 6, the degree of occurrence of silicon fluorine bonds over time when the temperature is 100K is smaller in carbon-doped silicon than in silicon.

That is, it can be confirmed that, depending on the temperature, the presence of carbon affects the degree of occurrence of silicon fluorine bonds differently.

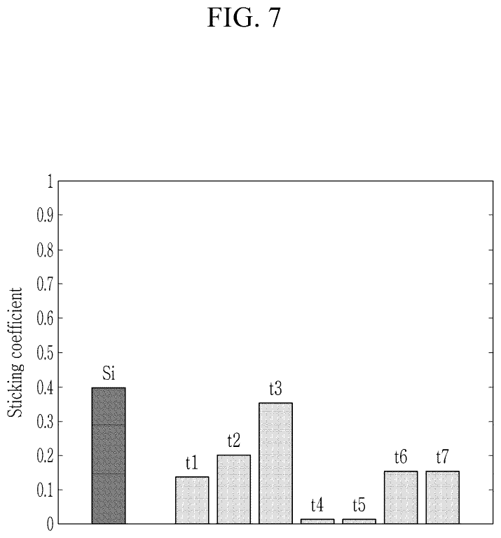

FIG. 7 is a graph showing a sticking coefficient in silicon and B₄C (001) plane.

Molecular dynamics is used to simulate the exposure of silicon and B₄C to HF plasma. The silicon is simulated on the (100) side. The B₄C (001) plane is simulated for t1, t2, t3, t4, t5, t6, and t7. The B₄C (001) surface refers to a surface cut along a specific crystal direction in the crystal structure. Even in the same direction, atoms exposed to the surface, the arrangement of atoms varies depending on the cutting position, and t1, t2, t3, t4, t5, t6, and t7 refer to such differences in cutting positions. Forcefield (interatomic potential) is implemented using ReaxFF. The temperature is simulated in the state of 100K.

The sticking coefficient is defined as the ratio of BF bonds to the total HF molecules adsorbed on the surface as shown in Equation 1 below.

$$Sticking coefficent = Number of BF bonds / Number of total HF molecules \qquad [ Equation 1 ]$$

Under the same conditions, 0.0876 HF molecules per Å² is adsorbed on the surface of silicon, and 0.1456 HF molecules per Å² is adsorbed on the surface of B₄C. In addition, the sticking coefficient is lower on the B₄C (001) plane than on the silicon. In particular, the B₄C (001) t4 plane and the B₄C (001) t5 plane show significantly low sticking coefficients. In the B4C (001) t4 plane and the B4C (001) t5 plane, the carbon atoms are exposed to the surface or are positioned adjacent to the surface. That is, it can be seen that the B₄C (001) t4 plane and the B₄C (001) t5 plane show significantly lower sticking coefficients due to the carbon atoms positioned on the surface or adjacent to the surface.

That is, as confirmed in FIGS. 5 and 6, it can be confirmed that in a low-temperature HF plasma environment, carbon reduces the degree to which it combines with fluorine. Additionally, in a low-temperature HF plasma environment, it can be confirmed that the carbon contained in boron carbide reduces the degree of bonding between boron and fluorine. Accordingly, as mentioned above, when the boron carbide included in the protection layer 238 has a higher carbon-to-boron ratio than B₄C, it can more effectively reduce the etching of the focus ring 23 by HF plasma. That is, boron carbide included in the protection layer 238 can more effectively reduce the etching of the focus ring 23 by HF plasma when the carbon content exceeds 20 at. %.

The protection layer 238 may be formed of boron carbide in an amount of 50 wt % or more. For example, the protection layer 238 may be provided as boron carbide. In this case, the fact that the protection layer 238 is provided as boron carbide does not mean that the protection layer 238 consists solely of 100% boron carbide; rather, impurities, in small amounts, may be included in the protection layer 238 in addition to boron carbide. For example, the protection layer 238 may be formed on the core 237 by a method such as reaction sintering, atmospheric pressure sintering, hot pressing, CVD, etc., and in the process of forming the protection layer 238, some impurities other than boron carbide may be included in the protection layer 238.

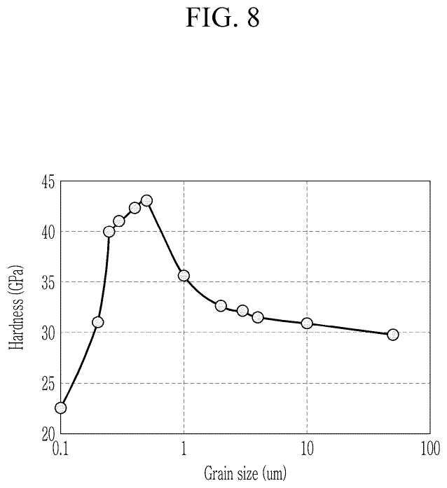

FIG. 8 is a diagram showing the relationship between the size and strength of the crystal grains of boron carbide.

It is simulated using molecular dynamics, and Forcefield (interatomic potential) is implemented using ReaxFF.

Referring to FIG. 8, it can be found that the size of the crystal grains of boron carbide varies depending on the strength. In addition, the size of boron carbide grains needs to be appropriately adjusted according to the efficiency of the process of forming boron carbide and the temperature of the process. Accordingly, it may be appropriate to set the grain size of boron carbide to 10 nm or more and 10 μm or less. In response, it may be appropriate to set the hardness of boron carbide to be 22 GPa or more and 44 GPa or less.

The material of the core 237 may be silicon (Si), silicon carbide (SiC), or the like.

The protection layer 238 may be positioned on at least a portion of the outer surface of the core 237. Accordingly, the protection layer 238 may be positioned in at least a portion of the outer surface of the focus ring 23. The protection layer 238 may be positioned in an exposed area that is exposed to the outside of the supporting member 20 in the focus ring 23. That is, the protection layer 238 may be positioned in an exposed area exposed to a space in which the plasma is positioned in the focus ring 23. The inner side surface 232 of the focus ring 23 may be blocked from being exposed to the outside where plasma may be positioned by the dielectric plate 21. The outer side surface 233 of the focus ring 23 may be blocked from being exposed to the outside where plasma may be positioned by the insulation ring 24. The lower surface 231 of the focus ring 23 may be positioned to be in contact with other components of the supporting member 20, or may be surrounded by the dielectric plate 21 and the insulation ring 24 to be blocked from being exposed to the outside where the plasma may be positioned. Accordingly, the exposed area of the focus ring 23 may be the upper surface 230 of the focus ring 23. That is, the exposed regions in the focus ring 23 may be the first surface 234, the second surface 235, and the connection surface 236 of the focus ring 23. In addition, a protection layer 238 may be positioned on the first surface 234, the second surface 235, and the connection surface 236.

In this case, the fact that the protection layer 238 is positioned in the exposed area does not mean that the protection layer 238 is positioned only in the exposed area. That is, the protection layer 238 may be positioned in at least a portion of the inner side surface 232, the outer side surface 233, and the lower surface 231 of the focus ring 23 in addition to the exposed area.

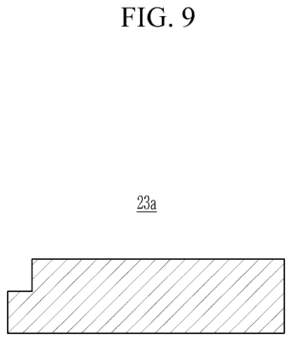

FIG. 9 is a cross-sectional view of a focus ring 23a according to embodiments.

Referring to FIG. 9, the focus ring 23a may be made of a material whose entire outer surface includes boron carbide. For example, the focus ring 23a may be made of a material containing boron carbide. In addition, the entire outer surface of the focus ring 23a may be provided as boron carbide. For example, the focus ring 23a may be provided as boron carbide.

In this case, the fact that the entire outer surface of the focus ring 23a or the focus ring 23a is provided as boron carbide does not mean that the entire outer surface of the focus ring 23a or the focus ring 23a consists solely of 100% boron carbide; rather, impurities, in small amounts, may be included in the protection layer in addition to boron carbide.

The boron carbide included in the focus ring 23a may be represented by Chemical Formula 1 described above. For example, boron carbide included in the protection layer may be B₂C, B₄C, B₅C, B₆C, B₁₃C₂, B₁₃C₃, B₅₀C₂, etc. In addition, boron carbide included in the protection layer may be a combination of at least two materials selected from the group consisting of B₂C, B₄C, B₅C, B₆C, B₁₃C₂, B₁₃C₃, B₅₀C₂, etc.

The boron carbide included in the focus ring 23a may be represented by Chemical Formula 2 described above. That is, boron carbide included in the protection layer may have a higher ratio of carbon to boron than B₄C.

In addition, the structure of the focus ring 23a is the same as or similar to that described in FIGS. 4 to 8, and thus repeated descriptions thereof are omitted.

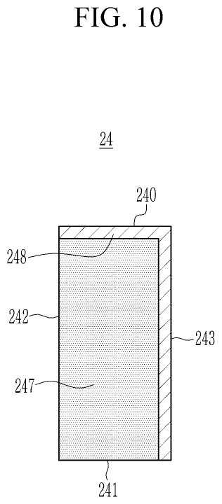

FIG. 10 is a cross-sectional view of the insulation ring 24 of FIG. 1.

Referring to FIG. 10, as the insulation ring 24 has a ring structure, the outer surface of the insulation ring 24 may include an upper surface 240, a lower surface 241, an inner side surface 242 positioned between the upper surface 240 and the lower surface 241 and facing a hole formed on the inner side and a dielectric plate 21, and an outer side surface 243 positioned between the upper surface 230 and the lower surface 241 and facing the chamber 10 in the opposite direction of the inner side surface 242 and.

At least a portion of the outer surface of the insulation ring 24 may be made of a material containing boron carbide. The insulation ring 24 may include an insulating part core 247 and an insulation part protection layer 248. The insulating part core 247 and the insulation part protection layer 248 may be formed of different materials. The insulation part protection layer 248 may include boron carbide.

The insulation part protection layer 248 may be formed of boron carbide in an amount of 50 wt % or more. For example, the insulation part protection layer 248 may be provided as boron carbide. In this case, the fact that the insulation part protection layer 248 is provided as boron carbide does not mean that the insulation part protection layer 248 consists solely of 100% boron carbide; rather, impurities, in small amounts, may be included in the insulation part protection layer 248 in addition to boron carbide. For example, the insulation part protection layer 248 may be formed on the insulating part core 247 by a method such as reaction sintering, atmospheric pressure sintering, hot pressing, CVD, or the like, and in the process of forming the insulation part protection layer 248, some impurities other than boron carbide may be included in the insulation part protection layer 248.

A material of the insulating part core 247 may be quartz or the like.

The insulation part protection layer 248 may be positioned on at least a portion of the outer surface of the insulating part core 247. Accordingly, the insulation part protection layer 248 may be positioned in at least a portion of the outer surface of the insulation ring 24. The insulation part protection layer 248 may be positioned in an exposed area that is exposed to the outside of the supporting member 20 in the insulation ring 24. That is, the insulation part protection layer 248 may be positioned in an exposed area exposed to a space in which the plasma is positioned in the insulation ring 24. The inner side surface 242 of the insulation ring 24 may be blocked from being exposed to the outside where plasma may be positioned by the focus ring 23. The lower surface 241 of the insulation ring 24 may be positioned to be in contact with other components of the supporting member 20 so as to be blocked from being exposed to the outside where the plasma may be positioned. Accordingly, the exposed areas of the insulation ring 24 may be the upper surface 240 of the insulation ring 24 and the outer side surface 243 of the insulation ring 24. In addition, the insulation part protection layer 248 may be positioned on the upper surface 240 of the insulation ring 24 and the outer side surface 243 of the insulation ring 24.

In this case, the fact that the insulation part protection layer 248 is positioned in the exposed area does not mean that the insulation part protection layer 248 is positioned only in the exposed area. That is, the insulation part protection layer 248 may be positioned in at least a portion of the inner side surface 242 of the insulation ring 24 and the lower surface 241 of the insulation ring 24 in addition to the exposed area.

The boron carbide included in the insulation part protection layer 248 may be represented by Chemical Formula 1 described above. For example, boron carbide included in the insulation part protection layer 248 may be B₂C, B₄C, B₅C, B₆C, B₁₃C₂, B₁₃C₃, or B₅₀C₂. In addition, the boron carbide included in the insulation part protection layer 248 may be a combination of at least two materials selected from the group consisting of B₂C, B₄C, B₅C, B₆C, B₁₃C₂, B₁₃C₃, and B₅₀C₂.

In addition, boron carbide included in the insulation part protection layer 248 may be represented by boron carbide as shown in Chemical Formula 3 below. y2 is a positive real number greater than 1.

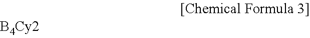

That is, boron carbide included in the insulation part protection layer 248 may have a higher ratio of carbon to boron than B₄C. That is, boron carbide included in the insulation part protection layer 248 may have a carbon content greater than 20 at. %, and a description thereof is the same as or similar to that described above with reference to FIGS. 5 to 7, and a repeated description thereof is omitted. In addition, boron carbide included in the insulation part protection layer 248 may have the grain size and strength described above in FIG. 8, and repeated descriptions thereof are omitted.

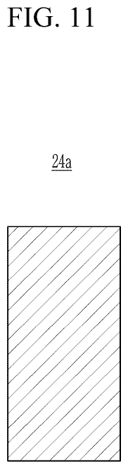

FIG. 11 is a cross-sectional view of an insulation ring 24a according to embodiments.

Referring to FIG. 11, the insulation ring 24a may be provided with a material including boron carbide on the entire outer surface. For example, the insulation ring 24a may be made of a material containing boron carbide. In addition, the entire outer surface of the insulation ring 24a may be provided as boron carbide. For example, the insulation ring 24a may be provided as boron carbide.

In this case, the fact that the entire outer surface of the insulation ring 24a or the insulation ring 24a itself is provided as boron carbide does not mean that the entire outer surface of the insulation ring 24a or the insulation ring 24a itself is composed of 100% boron carbide only, rather, it may also include cases where the entire outer surface of the insulation ring 24a or the insulation ring 24a contains small amounts of impurities in addition to boron carbide.

Boron carbide included in the insulation ring 24a may be represented by Chemical Formula 1 described above. For example, boron carbide included in the insulation ring 24a may be B₂C, B₄C, B₅C, B₆C, B₁₃C₂, B₁₃C₃, B₅₀C₂, etc. In addition, boron carbide included in the insulation ring 24a may be a combination of at least two materials selected from the group consisting of B₂C, B₄C, B₅C, B₆C, B₁₃C₂, B₁₃C₃, B₅₀C₂, etc.

Boron carbide included in the insulation ring 24a may be represented by Chemical Formula 3 described above. That is, boron carbide included in the insulation ring 24a may have a higher ratio of carbon to boron than B₄C.

In addition, the structure of the insulation ring 24a is the same as or similar to the insulation ring 24 described above with reference to FIG. 10, and thus repeated descriptions thereof will be omitted.

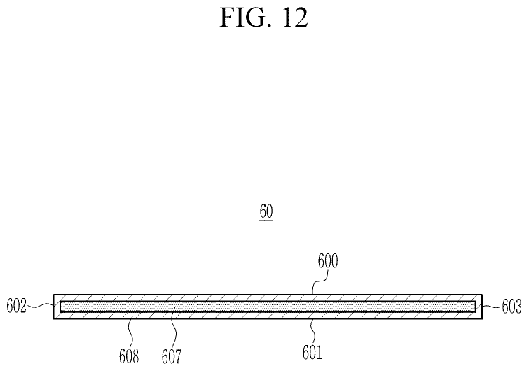

FIG. 12 is a cross-sectional view of the pressure control member 60 of FIG. 1.

Referring to FIG. 12, the outer surface of the pressure control member 60 may include an upper surface 600, a lower surface 601, an inner side surface 602 positioned between the upper surface 600 and the lower surface 601 and facing the hole formed on the inside and the supporting member 20, and an outer side surface 603 positioned between the upper surface 600 and the lower surface 601 and facing the chamber 10 in the opposite direction of the inner side surface 602.

At least a portion of the outer surface of the pressure control member 60 may be made of a material containing boron carbide. The pressure control member 60 may include a pressure control part core 607 and a pressure control part protection layer 608. The pressure control part core 607 and the pressure control part protection layer 608 may be made of different materials. The pressure control part protection layer 608 may include boron carbide.

The pressure control part protection layer 608 may be made of boron carbide in an amount of 50 wt % or more. For example, the pressure control part protection layer 608 may be provided as boron carbide. At this time, the fact that the pressure control part protection layer 608 is provided as boron carbide does not mean that the pressure control part protection layer 608 is composed of 100% boron carbide only, rather, it may include cases where the pressure control part protection layer 608 contains small amount of impurities in addition to boron carbide. For example, the pressure control part protection layer 608 may be formed on the pressure control part core 607 by a method such as reaction sintering, atmospheric pressure sintering, hot pressing, CVD, or the like, and in the process of forming the pressure control part protection layer 608, some impurities other than boron carbide may be included in the pressure control part protection layer 608.

The material of the pressure control part core 607 may be quartz or the like.

The pressure control part protection layer 608 may be positioned on at least a portion of the outer surface of the pressure control part core 607. Accordingly, the pressure control part protection layer 608 may be positioned in at least a portion of the outer surface of the pressure control member 60. The pressure control part protection layer 608 may be positioned in an exposed area exposed to the outside of the supporting member 20 in the pressure control member 60. That is, the pressure control part protection layer 608 may be positioned in an exposed area exposed to a space in which the plasma is positioned in the pressure control member 60. A pressure control part protection layer 608 may be positioned on the upper surface 600 of the pressure control member 60. A pressure control part protection layer 608 may be positioned on the lower surface 601 of the pressure control member 60. A pressure control part protection layer 608 may be positioned on the outer side surface 603 of the pressure control member 60. A pressure control part protection layer 608 may be positioned on the inner side surface 602 of the pressure control member 60.

Boron carbide included in the pressure control part protection layer 608 may be represented by Chemical Formula 1 described above. For example, boron carbide included in the pressure control part protection layer 608 may be B₂C, B₄C, B₅C, B₆C, B₁₃C₂, B₁₃C₃, or B₅₀C₂. In addition, boron carbide included in the pressure control part protection layer 608 may be a combination of at least two materials selected from the group consisting of B₂C, B₄C, B₅C, B₆C, B₁₃C₂, B₁₃C₃, and B₅₀C₂.

In addition, boron carbide included in the pressure control part protection layer 608 may be represented by boron carbide as shown in Chemical Formula 4 below. Y3 is a positive real number greater than 1.

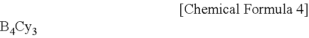

That is, boron carbide included in the pressure control part protection layer 608 may have a higher ratio of carbon to boron than B₄C.

That is, boron carbide included in the pressure control part protection layer 608 may have a carbon content of greater than 20 at. %, and a description thereof is the same as or similar to that described above with reference to FIGS. 5 to 7, and a repeated description thereof is omitted. In addition, boron carbide included in the pressure control part protection layer 608 may have the grain size and strength described above in FIG. 8, and repeated descriptions thereof are omitted.

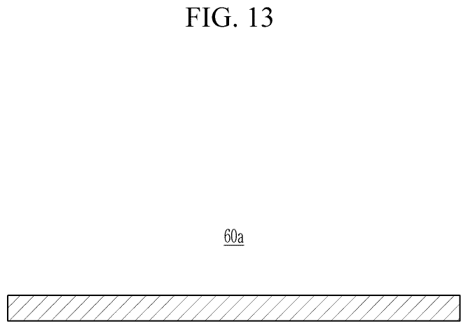

FIG. 13 is a cross-sectional view of the pressure control member 60a according to embodiments.

Referring to FIG. 13, the pressure control member 60a may be provided with a material whose entire outer surface includes boron carbide. As an example, the pressure control member 60a may be provided with a material including boron carbide. Additionally, the entire outer surface of the pressure control member 60a may be provided with boron carbide. As an example, the pressure control member 60a may be provided with boron carbide.

In this case, the fact that the entire outer surface of the pressure control member 60a or that the pressure control member 60a is provided with boron carbide does not solely mean that the entire outer surface of the pressure control member 60a or the pressure control member 60a is 100% made of boron carbide, but it may also include cases where small amount of impurities is present in addition to boron carbide on the entire outer surface of the pressure control member 60a or in the pressure control member 60a.

Boron carbide included in the pressure control member 60a may be represented by Chemical Formula 1 described above. For example, boron carbide included in the pressure control member 60a may be B₂C, B₄C, B₅C, B₆C, B₁₃C₂, B₁₃C₃, and B₅₀C₂. In addition, boron carbide included in the pressure control member 60a may be a combination of at least two materials selected from the group consisting of B₂C, B₄C, B₅C, B₆C, B₁₃C₂, B₁₃C₃, B₅₀C₂, etc.

Boron carbide included in the pressure control member 60a may be represented by Chemical Formula 4 described above. That is, boron carbide included in the pressure control member 60a may have a higher ratio of carbon to boron than B₄C.

In addition, a structure of the pressure control member 60a is the same as or similar to that of the pressure control member 60 of FIG. 12, and thus repeated descriptions thereof will be omitted.

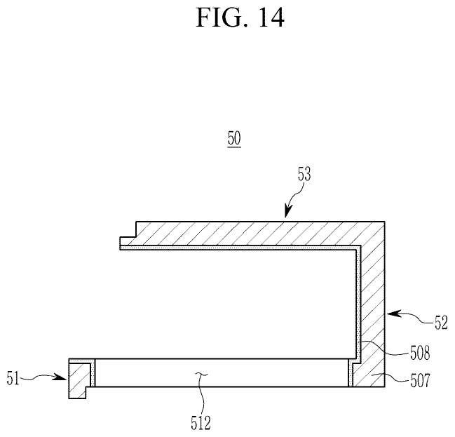

FIG. 14 is a cross-sectional view of the baffle 50 of FIG. 1.

Referring to FIG. 14, at least a portion of the outer surface of the baffle 50 may be made of a material including boron carbide. The baffle 50 may include a frame 507 and a frame protection layer 508. The frame 507 and the frame protection layer 508 may be provided with different materials. The frame protection layer 508 may include boron carbide.

The frame protection layer 508 may be composed of boron carbide at a content of 50 wt % or more. As an example, the frame protection layer 508 may be provided from boron carbide. In this case, the fact that the frame protection layer 508 is provided as boron carbide does not mean that the frame protection layer 508 consists solely of 100% boron carbide; rather, impurities in small amounts may be included in the frame protection layer 508 in addition to boron carbide. For example, the frame protection layer 508 may be formed on the frame 507 by a method such as reaction sintering, atmospheric pressure sintering, hot pressing, or CVD, and during the process of forming the frame protection layer 508, some impurities other than boron carbide may be included in the frame protection layer 508. The material of the frame 507 may be silicon, etc.

The frame protection layer 508 may be positioned on at least a portion of the outer surface of the frame 507. Accordingly, the frame protection layer 508 may be positioned in at least a portion of the outer surface of the baffle 50. The frame protection layer 508 may be positioned on the surface of the baffle 50 facing the plasma excitation space CS. The frame protection layer 508 may be positioned on the upper surface of the exhaust control part 51 facing the plasma excitation space CS. The frame protection layer 508 may be positioned on the inner side surface of the side partition portion 52 facing the plasma excitation space CS. The frame protection layer 508 may be positioned on a lower surface of the upper partition portion 53 facing the plasma excitation space CS. The frame protection layer 508 may be positioned on the sidewall of the discharge hole 512.

The boron carbide included in the frame protection layer 508 may be represented by Chemical Formula 1 described above. For example, boron carbide included in the frame protection layer 508 may be B₂C, B₄C, B₅C, B₆C, B₁₃C₂, B₁₃C₃, B₅₀C₂, etc. In addition, boron carbide included in the frame protection layer 508 may be a combination of at least two materials selected from the group consisting of B₂C, B₄C, B₅C, B₆C, B₁₃C₂, B₁₃C₃, B₅₀C₂, etc.

In addition, boron carbide included in the frame protection layer 508 may be represented by boron carbide as shown in Chemical Formula 5 below. y4 is a positive real number greater than 1.

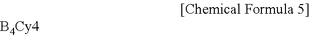

That is, boron carbide included in the frame protection layer 508 may have a higher ratio of carbon to boron than B₄C.

That is, the boron carbide included in the frame protection layer 508 may have a carbon content exceeding 20 at. %, and the description thereof is the same as or similar to that described above in FIGS. 5 to 7, and repeated description is omitted. In addition, boron carbide included in the frame protection layer 508 may have the crystal grain size and strength described above in FIG. 8, and a repeated description thereof is omitted.

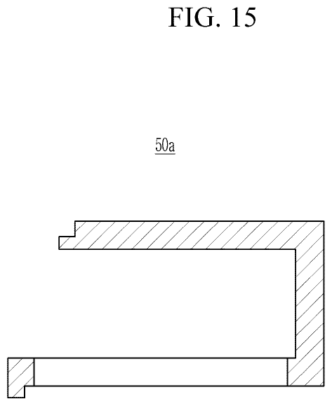

FIG. 15 is a cross-sectional view of a baffle 50a according to embodiments.

Referring to FIG. 15, the baffle 50a may be provided with a material including boron carbide on the entire outer surface. As an example, the baffle 50a may be provided from a material including boron carbide. Additionally, the entire outer surface of the baffle 50a may be provided with boron carbide. As an example, the baffle 50a may be provided from boron carbide.

In this case, the fact that the entire outer surface of the baffle 50a or the baffle (50a) is provided as boron carbide does not mean that the entire outer surface of the baffle 50a or the baffle 50a consists solely of 100% boron carbide; rather, impurities, in small amounts, may be included in the entire outer surface of the baffle 50a or the baffle 50a in addition to boron carbide.

Boron carbide included in the baffle 50a may be represented as in the Chemical Formula 1 described above. For example, boron carbide included in the baffle 50a may be B₂C, B₄C, B₅C, B₆C, B₁₃C₂, B₁₃C₃, B₅₀C₂, etc. Additionally, the boron carbide included in the baffle 50a may be a combination of at least two materials selected from the group consisting of B₂C, B₄C, B₅C, B₆C, B₁₃C₂, B₁₃C₃, B₅₀C₂, etc.

The boron carbide contained in the baffle 50a may be represented by Chemical Formula 5 described above. That is, boron carbide included in the baffle 50a may have a higher ratio of carbon to boron than B₄C. That is, the carbon content of boron carbide contained in the baffle 50a may exceed 20 at. %, and a description thereof is the same as or similar to that described in FIGS. 5 to 7, and a repeated description thereof is omitted. In addition, boron carbide included in baffle 50a may have the grain size and strength described above in FIG. 8, and repeated descriptions thereof are omitted.

In the substrate processing apparatus 1 according to embodiments, the lifespan of components positioned inside the chamber 10 may be increased. Accordingly, in the substrate processing apparatus 1 according to embodiments, the replacement period of components positioned inside the chamber 10 is increased, and accordingly, the operation efficiency may be improved. In the substrate processing apparatus 1, in the process of processing the substrate through plasma, a configuration positioned inside the chamber 10 may be etched together by plasma. When the dielectric plate 21 is cooled to implement a low-temperature etching process, plasma is more effectively adsorbed to the surface of the substrate cooled together with the dielectric plate 21, thereby improving substrate processing efficiency. In addition, as the dielectric plate 21 is cooled, a configuration positioned to be heat transferred may be cooled together with the dielectric plate 21. This may increase the degree to which the configuration of the substrate processing apparatus 1 is etched by plasma. A substrate processing apparatus 1 according to one embodiment is provided such that an area exposed to plasma includes boron carbide. Boron carbide can increase the life of components positioned within the chamber 10 by reducing the degree to which plasma is adsorbed onto surfaces. In addition, a substrate processing apparatus 1 according to one embodiment is provided to process a substrate through HF plasma, and an area exposed to the plasma is provided to include boron carbide, thereby reducing the degree to which plasma is adsorbed on the surface of a component positioned inside the chamber 10.

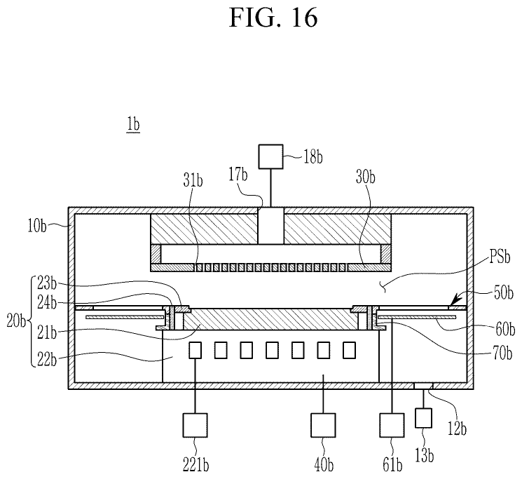

FIG. 16 is a diagram illustrating a substrate processing apparatus 1b according to embodiments.

Referring to FIG. 16, a substrate processing apparatus 1b according to embodiments may include a chamber 10b, a supporting member 20b, a plasma excitation member 30b, a source power supply unit 40b, a baffle 50b, and a pressure control member 60b.

The chamber 10b provides a process space PS in which a substrate processing process is performed. An exhaust hole 12b may be positioned at one side of the chamber 10b. The exhaust hole 12b may be formed in a lower region of the chamber 10b. An exhaust member 13b may be connected to the exhaust hole 12b of the chamber 10b. A gas inlet 17b may be positioned on one side of the chamber 10b, and a gas supply member 18b may be connected to the gas inlet 17b of the chamber 10b.

The supporting member 20b is disposed inside the chamber 10b. The supporting member 20b supports the substrate.

The supporting member 20 may include a dielectric plate 21b, a body 22b, a focus ring 23b, and an insulation ring 24b. A chiller 221b may be connected to the supporting member 20b.

The plasma excitation member 30b allows energy for excitation of plasma to be applied to the process space PSb. The lower surface of the plasma excitation member 30b may be positioned inside the chamber 10b.

A distribution hole 31b for supplying the gas introduced into the gas inlet 17b may be formed in the plasma excitation member 30b.

The source power supply unit 40b provides power for plasma excitation. The source power supply unit 40b may be connected to one of the supporting member 20b and the plasma excitation member 30b, and the other one may be grounded. In addition, the source power supply unit 40b may be connected to the supporting member 20b and the plasma excitation member 30b, respectively.

A pressure control member 60b may be disposed below the baffle 50b. The pressure control member 60b may be connected to the elevating member 61b to be movable in an upward and downward direction.

Details of the configuration connected to the chamber 10b, the configuration connected to the chamber 10b, the supporting member 20b, the configuration connected to the supporting member 20b, the plasma excitation member 30b, the source power supply unit 40b, the pressure control member 60b, and the pressure control member 60b are the same as or similar to those connected to the chamber 10, the configuration connected to the chamber 10, the supporting member 20, the configuration connected to the supporting member 20, and the plasma excitation member 30, the source power supply unit 40, the pressure control members 60 and 60a which are described in FIGS. 1 and 4 to 13, and the pressure control members 60 and 60a, and repeated descriptions thereof are omitted.

The baffle 50b divides a space positioned above the supporting member 20b and a space positioned below the chamber 10b from each other. The baffle 50b is disposed around the outer periphery of the supporting member 20b. The baffle 50b may be disposed around the outer periphery of the focus ring 23b. The baffle 50b may be disposed around the outer periphery of the insulation ring 24b.

The baffle 50b may have a ring structure. The center of the baffle 50b may be positioned to correspond to the center of the supporting member 20b. An outer region of the baffle 50b may be positioned adjacent to the chamber 10b. For example, the outer region of the baffle 50b may be positioned to be in contact with the chamber 10b. In addition, the outer area of the baffle 50b and the chamber 10b may be provided to contact each other through a liner or the like. The baffle 50b may be grounded. For example, the baffle 50b may be connected to the ground member 70b. Specific content of the ground member 70b is the same as or similar to that of the ground member 70 of FIG. 1, and thus repeated descriptions thereof will be omitted.

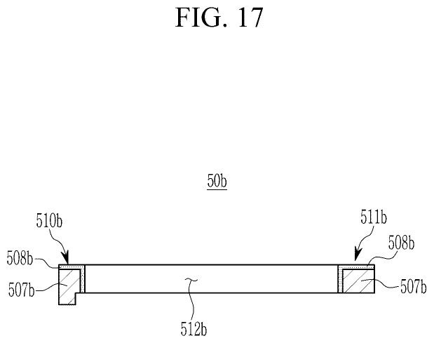

FIG. 17 is a cross-sectional view of the baffle 50b of FIG. 16.

Referring to FIG. 17, a baffle 50b may include a connection part 510b and an exhaust part 511b. A plurality of discharge holes 512b may be formed in the baffle 50b. The discharge holes 512b are formed to penetrate between an upper surface and a lower surface of the baffle 50b. The discharge hole 512b may be formed in the exhaust part 511b.

The baffle 50b may have the same or similar structure as the exhaust control part 51 described above in FIGS. 2 and 3, and repeated descriptions thereof will be omitted.

At least a portion of the outer surface of the baffle 50b may be made of a material containing boron carbide. The baffle 50b may include a frame 507b and a frame protection layer 508b. The frame 507b and the frame protection layer 508b may be provided with different materials. The frame protection layer 508b may include boron carbide.

The frame protection layer 508b may be composed of boron carbide at a content of 50 wt % or more. As an example, the frame protection layer 508b may be provided from boron carbide. In this case, the fact that the frame protection layer 508b is provided as boron carbide does not mean that the frame protection layer 508b consists solely of 100% boron carbide; rather, impurities, in small amounts, may be included the frame protection layer 508b in addition to boron carbide. For example, the frame protection layer 508b may be formed on the frame 507b by a method such as reaction sintering, atmospheric pressure sintering, hot pressing, or CVD, and during the process of forming the frame protection layer 508b, some impurities other than boron carbide may be included in the frame protection layer 508b.

The material of the frame 507b may be silicon, etc.

The frame protection layer 508b may be positioned on at least a portion of the outer surface of the frame 507b. Accordingly, the frame protection layer 508b may be positioned in at least a portion of the outer surface of the baffle 50b. The frame protection layer 508b may be positioned on an upper surface of the baffle 50b. The frame protection layer 508b may be positioned on a sidewall of the discharge hole 512b.

The boron carbide included in the frame protection layer 508b may be represented by Chemical Formula 1 described above. For example, boron carbide included in the frame protection layer 508b may be B₂C, B₄C, B₅C, B₆C, B₁₃C₂, B₁₃C₃, B₅₀C₂, etc. In addition, boron carbide included in the frame protection layer 508b may be a combination of at least two materials selected from the group consisting of B₂C, B₄C, B₅C, B₆C, B₁₃C₂, B₁₃C₃, B₅₀C₂, etc.

In addition, boron carbide included in the frame protection layer 508b may be represented by boron carbide as shown in Chemical Formula 6 below. y5 is a positive real number greater than 1.

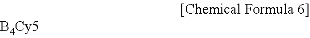

That is, boron carbide included in the frame protection layer 508b may have a higher ratio of carbon to boron than B₄C.

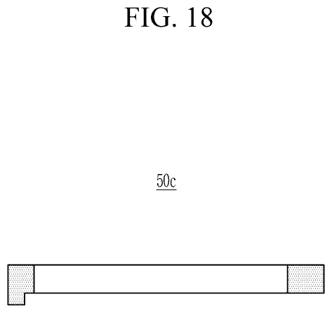

FIG. 18 is a cross-sectional view of a baffle 50c according to embodiments.

Referring to FIG. 18, the baffle 50c may be provided with a material including boron carbide on the entire outer surface. As an example, the baffle 50c may be provided from a material including boron carbide. Additionally, the entire outer surface of the baffle 50c may be provided with boron carbide. As an example, the baffle 50c may be provided from boron carbide.

In this case, the fact that the entire outer surface of the baffle 50c or the baffle 50c is provided as boron carbide does not mean that the entire outer surface of the baffle 50c or the baffle 50c consists solely of 100% boron carbide; rather, impurities, in small amounts, may be included in the entire outer surface of the baffle 50c or the baffle 50c in addition to boron carbide.

Boron carbide included in the baffle 50c may be represented as in the chemical formula 1 described above. For example, boron carbide included in the baffle 50c may be B₂C, B₄C, B₅C, B₆C, B₁₃C₂, B₁₃C₃, B₅₀C₂, etc. Additionally, the boron carbide included in the baffle 50c may be a combination of at least two materials selected from the group consisting of B₂C, B₄C, B₅C, B₆C, B₁₃C₂, B₁₃C₃, B₅₀C₂, etc.

Boron carbide included in the baffle 50c may be represented as in the chemical formula 6 described above. That is, boron carbide included in the baffle 50c may have a higher ratio of carbon to boron than B₄C.

In addition, the structure of the baffle 50c is the same as or similar to that of the baffle 50b described above in FIG. 13, and thus repeated descriptions thereof will be omitted.

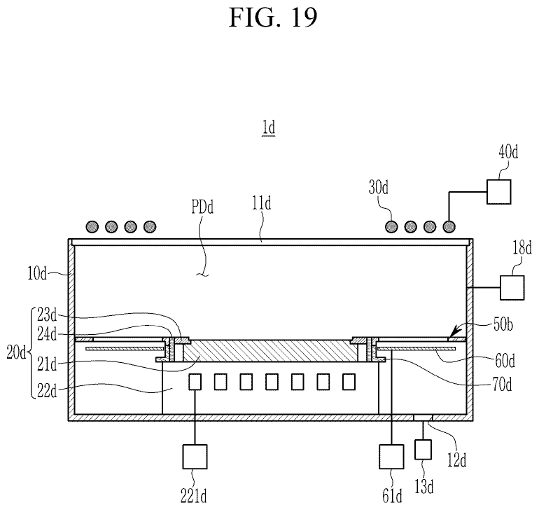

FIG. 19 is a diagram illustrating a substrate processing apparatus 1d according to embodiments.

Referring to FIG. 19, a substrate processing apparatus 1d according to embodiments may include a chamber 10d, a supporting member 20d, a plasma excitation member 30d, a source power supply unit 40d, and a baffle 50d.

The chamber 10d provides a process space PSd in which a substrate processing process is performed. An exhaust hole 12d may be positioned at one side of the chamber 10d. The exhaust hole 12d may be formed in a lower region of the chamber 10d. An exhaust member 13d may be connected to the exhaust hole 12d of the chamber 10d. At least a portion of the upper wall 11d of the chamber 10d may be provided as a dielectric substance. A gas supply member 18d may be connected to one side of the chamber 10d.

The supporting member 20d is disposed inside the chamber 10d. The supporting member 20d supports the substrate.

The supporting member 20d may include a dielectric plate 21d, a body 22d, a focus ring 23d, and an insulation ring 24d. A chiller 221d may be connected to the supporting member 20d.

The plasma excitation member 30d allows energy for excitation of plasma to be applied to the process space PSd. The plasma excitation member 30d may be disposed inside the chamber 10d. The plasma excitation member 30d may be provided in an antenna structure. The plasma excitation member 30d may be disposed adjacent to the upper wall 11d of the chamber 10d. The plasma excitation member 30d may be disposed to face the upper wall 11d of the chamber 10d in an upward and downward direction.

The source power supply unit 40d provides power for plasma excitation. The source power supply unit 40d may be connected to the plasma excitation member 30d. The source power supply unit 40d may include a high frequency power source that generates high frequency power. The source power supply unit 40d may include RF power. Accordingly, the plasma excitation member 30d generates electromagnetic waves for plasma excitation through the power provided by the source power supply unit 40d.

The baffle 50d divides a space positioned above the supporting member 20d and a space positioned below the chamber 10d from each other. The baffle 50d is disposed around the outer periphery of the supporting member 20d. The baffle 50d may be disposed around the outer periphery of the focus ring 23d. The baffle 50d may be disposed around the outer periphery of the insulation ring 24d.

The baffle 50d may have a ring structure. The center of the baffle 50d may be positioned to correspond to the center of the supporting member 20d. An outer region of the baffle 50d may be positioned adjacent to the chamber 10d. For example, the outer region of the baffle 50d may be positioned to be in contact with the chamber 10d. In addition, the outer area of the baffle 50d and the chamber 10d may be provided to contact each other through a liner or the like. The baffle 50d may be grounded. For example, the baffle 50d may be connected to the ground member 70d. Specific content of the ground member 70d is the same as or similar to that of the ground member 70 of FIG. 1, and thus repeated descriptions thereof will be omitted.

In addition, the baffle 50d may be provided so that at least a part of the outer surface includes a boron carbide material, and the contents thereof are the same as or similar to those described in FIGS. 13 and 18, so repeated explanations are omitted.

The details of the chamber 10d, the configuration connected to the chamber 10d, the supporting member 20d, and the configuration connected to the supporting member 20d are the same as or similar to the configurations connected to the chamber 10, the configuration connected to the chamber 10, the supporting member 20 and the configuration connected to the supporting member 20 which are described in FIGS. 1 and 4 to 13, and repeated descriptions thereof are omitted.

A pressure control member 60d may be disposed below the baffle 50d. The pressure control member 60d may be connected to the elevating member 61d. The contents thereof are the same as or similar to those described in FIGS. 1, 12, and 13, and thus repeated descriptions thereof will be omitted. Also, the pressure control member 60d may be omitted.

Although the embodiments of the disclosure have been described in detail above, the scope of the present disclosure is not limited to the scope of the present disclosure, but various modifications and improvements of the person of an order skill in the art using the basic concept of the present disclosure defined in the following claim range also belong to the scope of the present disclosure.

### DESCRIPTION OF SYMBOLS

10: chamber
18: gas supply member
20: supporting member
21: dielectric plate
22: body
23: focus ring
24: insulation ring
30: plasma excitation member
40: source power supply unit
50: baffle
60: pressure control member
220: refrigerant flow path
221: chiller

What is claimed is:

1. A substrate processing apparatus comprising:
a chamber;
a plasma excitation member that allows energy to be applied for excitation of plasma; and
a supporting member disposed inside the chamber and supporting a substrate,
wherein the supporting member is provided with material in which at least a portion of an outer surface of the supporting member comprises boron carbide represented by the chemical formula, 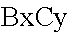
wherein x, y are positive real numbers.

2. The substrate processing apparatus
of claim 1, wherein
the supporting member comprises:
a dielectric plate; and
a focus ring disposed around an outer periphery of the dielectric plate, and
wherein at least a portion of an outer surface of the focus ring is provided with a material comprising boron carbide.

3. The substrate processing apparatus
of claim 2, wherein
the supporting member further comprises:
an insulation ring disposed around an outer periphery of the focus ring, and
at least a portion of an outer surface of the insulation ring is provided with a material comprising boron carbide.

4. The substrate processing apparatus
of claim 1 further comprises:
a baffle disposed around an outer periphery of the supporting member; and
a pressure control member disposed around the outer periphery of the supporting member and below the baffle and movable in an upward and downward direction,
wherein at least a portion of an outer surface of the pressure control member comprises boron carbide.

5. The substrate processing apparatus of claim 4, wherein the pressure control member is provided entirely on an outer surface of the pressure control member with a material comprising boron carbide.

6. The substrate processing apparatus
of claim 4, wherein
at least a portion of an outer surface of the baffle is provided with a material comprising boron carbide.

7. The substrate processing apparatus
of claim 1, wherein
the boron carbide is represented by the chemical formula, 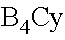
wherein y is a positive real number greater than 1.

8. A substrate processing apparatus comprising:
a chamber;
a plasma excitation member that allows energy to be applied for excitation of plasma; and
a supporting member disposed inside the chamber and supporting a substrate,
wherein the supporting member comprises:
a dielectric plate; and
a focus ring disposed around an outer periphery of the dielectric plate, and
wherein at least a portion of the outer surface of the focus ring is provided with a material comprising boron carbide represented by the chemical formula, 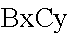
wherein x, y are positive real numbers.

9. The substrate processing apparatus
of claim 8, wherein
the focus ring comprises:
a core; and
a protection layer positioned on the core;
wherein the protection layer comprises boron carbide.

10. The substrate processing apparatus
of claim 8, wherein
the focus ring is provided with a material comprising boron carbide.

11. The substrate processing apparatus
of claim 8, wherein
the supporting member further comprises:
an insulation ring disposed around an outer periphery of the focus ring, and
at least a portion of an outer surface of the insulation ring is provided with a material comprising boron carbide.

12. The substrate processing apparatus
of claim 11, wherein
the insulation ring comprises:
an insulating part core; and
an insulation part protection layer positioned on the insulating part core, and
wherein the insulation part protection layer comprises boron carbide.

13. The substrate processing apparatus
of claim 11, wherein
the insulation ring is provided with a material comprising boron carbide.

14. The substrate processing apparatus
of claim 8, further comprising:
a baffle disposed around an outer periphery of the supporting member; and
a pressure control member disposed around the outer periphery of the supporting member and below the baffle, and capable of moving in an upward and downward direction,
wherein at least a portion of an outer surface of the pressure control member is provided with a material comprising boron carbide.

15. The substrate processing apparatus
of claim 14, wherein
the pressure control member comprises:
a pressure control part core; and
a pressure control part protection layer positioned on the pressure control part core, and
wherein the pressure control part protection layer comprises boron carbide.

16. The substrate processing apparatus
of claim 14, wherein
the pressure control member is provided with a material comprising boron carbide.

17. A substrate processing apparatus comprising:
a chamber;
a plasma excitation member that allows energy to be applied for excitation of plasma;
a supporting member disposed inside the chamber and supporting a substrate;
a chiller connected to the supporting member; and
a gas supply member connected to the chamber,
wherein the supporting member comprises:
a dielectric plate;
a focus ring disposed around an outer periphery of the dielectric plate; and
an insulation ring disposed around an outer periphery of the focus ring, and
wherein at least a portion of an outer surface of the focus ring and the insulation ring is provided with a material comprising boron carbide represented by the chemical formula, 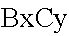
wherein x, y are positive real numbers.

18. The substrate processing apparatus
of claim 17, wherein:
the gas supply member supplies a process gas for excitation of HF plasma, and
the chiller is capable of cooling the dielectric plate to 0° C. or lower.

19. The substrate processing apparatus
of claim 17, wherein
a size of boron carbide in at least a portion of the outer surface of the focus ring and the insulation ring is 10 nm or more and 10 μm or less.

20. The substrate processing apparatus
of claim 17, wherein
a hardness of boron carbide of at least a portion of the outer surface of the focus ring and the insulation ring is 22 GPa or more and 44 GPa or less.
